(19) United States
(12) Patent Application Publication
(10) Pub. No.: US 2025/0357413 A1
(43) Pub. Date: Nov. 20, 2025

(54) SEMICONDUCTOR PACKAGE

(71) Applicant: Samsung Electronics Co., Ltd., Suwon-si (KR)

(72) Inventors: Junyun Kweon, Suwon-si (KR); Wooju Kim, Suwon-si (KR); Junggeun Shin, Suwon-si (KR); Junho Yoon, Suwon-si (KR); Dayoung Cho, Suwon-si (KR); Jinwook Hong, Suwon-si (KR)

(21) Appl. No.: 18/975,365

(22) Filed: Dec. 10, 2024

(30) Foreign Application Priority Data
May 14, 2024 (KR) 10-2024-0062876

(51) Int. Cl. H01L 23/00; H01L 23/31; H01L 23/498; H01L 25/065

(52) U.S. Cl. CPC H01L 24/48; H01L 23/3135; H01L 23/49816; H01L 23/49822; H01L 24/08; H01L 24/49; H01L 24/73; H01L 25/0657; H01L 24/32; H01L 2224/08112; H01L 2224/32113; H01L 2224/32145; H01L 2224/4807; H01L 2224/48235; H01L 2224/49109; H01L 2224/73265; H01L 2225/0651; H01L 2225/06548; H01L 2225/06562; H01L 2924/3862

(57) ABSTRACT

A semiconductor package includes a redistribution structure including redistribution vias extending from redistribution layers into an insulating layer, a plurality of semiconductor chips stacked on the redistribution structure, a molded layer between the redistribution structure and the plurality of semiconductor chips, connection wires electrically connecting corresponding connection pads and redistribution vias, and connection bumps below the redistribution structure. The connection wires include a first portion extending from each of the connection pads at a first inclination angle for a bottom surface of the molded layer, and a second portion extending from the first portion at a second inclination angle, narrower than the first inclination angle for the bottom surface of the molded layer. The second portion has an end surface in contact with corresponding redistribution vias, and each of the redistribution vias has a top surface in contact with the end surface of the second portion.

### CROSS-REFERENCE TO RELATED APPLICATION(S)

This application claims the benefit under 35 USC 119(a) of Korean Patent Application No. 10-2024-0062876 filed on May 14, 2024 in the Korean Intellectual Property Office, the entire disclosure of which is incorporated herein by reference for all purposes.

### BACKGROUND

With the development of the electronics industry, demands for higher functionality, higher speed, and smaller electronic components are increasing. According to this trend, semiconductor packaging technology in which a plurality of semiconductor chips are embedded in a single package is being developed. Accordingly, there is a need for a technology that may ensure connection reliability of each of a plurality of semiconductor chips.

### SUMMARY

The present inventive concept relates to semiconductor packages.

Example embodiments provide a semiconductor package having improved reliability.

According to example embodiments, a semiconductor package includes a package substrate. The package substrate includes an insulating layer, redistribution layers below the insulating layer, and redistribution vias extending from the redistribution layers into the insulating layer. The semiconductor package further includes a plurality of semiconductor chips respectively having a front surface on which connection pads are disposed and a rear surface opposite to the front surface, and stacked on the package substrate such that the front surface faces the package substrate; a molded layer between the package substrate and the plurality of semiconductor chips; a plurality of connection wires extending within the molded layer and electrically connecting to corresponding ones of the connection pads and corresponding ones of the redistribution vias; and connection terminals electrically connected to the redistribution layers and disposed below the package substrate. Each of the plurality of connection wires includes a first portion extending from a corresponding one of the connection pads at a first inclination angle with respect to a bottom surface of the molded layer, and a second portion extending from the first portion and having a second inclination angle with respect to the bottom surface of the molded layer. The second inclination angle is less than the first inclination angle. Each second portion of the plurality of connection wires has an end surface in contact with a corresponding one of the redistribution vias.

According to example embodiments, a semiconductor package includes a plurality of semiconductor chips respectively having a front surface on which connection pads are disposed and a rear surface opposite to the front surface, and stacked such that the front surface faces downwards; a molded layer encapsulating the plurality of semiconductor chips; a plurality of connection wires respectively extending from the connection pads of the plurality of semiconductor chips to a bottom surface of the molded layer; and a package substrate disposed below the molded layer and including redistribution layers and redistribution vias electrically connecting the redistribution layers and the plurality of connection wires. Each of the plurality of connection wires include a vertical portion extending from the connection pads in a direction toward the bottom surface of the molded layer, and a diagonal portion extending diagonally between the vertical portion and the redistribution vias, and the diagonal portion is exposed to the bottom surface of the molded layer and contacting the a corresponding one of redistribution vias. A maximum width of each of the diagonal portions exposed to the bottom surface of the molded layer is greater than a diameter of a corresponding one of the plurality of connection wires.

According to example embodiments, a semiconductor package includes a plurality of semiconductor chips respectively having connection pads, and stacked such that the connection pads face downwards; a molded layer encapsulating the plurality of semiconductor chips; a plurality of connection wires respectively extending from the connection pads of the plurality of semiconductor chips to a bottom surface of the molded layer; and a package substrate disposed below the molded layer and including redistribution layers and redistribution vias electrically connecting the redistribution layers to the plurality of connection wires. Each of the plurality of connection wires includes a vertical portion in contact with a corresponding one of the connection pads, and a diagonal portion extending diagonally between the vertical portion and a corresponding one of the redistribution vias, and the diagonal portion is exposed to the bottom surface of the molded layer and contacting the redistribution vias. In a plan view, each of the diagonal portions have an end surface of oval shape exposed to the bottom surface of the molded layer. The plurality of connection wires include a pair of connection wires that are adjacent to each other. The pair of connection wires have major axes of the oval shape respectively, and the major axes is different from each other.

### BRIEF DESCRIPTION OF DRAWINGS

The above and other aspects, features, and advantages of the present inventive concept will be more clearly understood from the following detailed description taken in conjunction with the accompanying drawings, in which:

FIG. 1A is a cross-sectional view of a semiconductor package according to an example embodiment, and FIG. 1B is a partially enlarged view of area ‘A’ of FIG. 1A;

FIGS. 2A to 2C are perspective views illustrating end surfaces of connection wires in contact with redistribution vias;

FIGS. 3A to 3C are diagrams illustrating semiconductor packages according to illustrative modifications;

FIG. 4A is a cross-sectional view of a semiconductor package according to an example embodiment, and FIG. 4B is a partially enlarged view of area ‘A1’ of FIG. 4A;

FIG. 5A is a cross-sectional view of a semiconductor package according to an example embodiment, and FIG. 5B is a partial enlarged view of area ‘A2’ of FIG. 5A;

FIG. 6A is a cross-sectional view of a semiconductor package according to an example embodiment, and FIG. 6B is a partial enlarged view of area ‘A3’ of FIG. 6A;

FIG. 7A is a cross-sectional view of a semiconductor package according to an example embodiment, and FIG. 7B is a partial enlarged view of area ‘A4’ of FIG. 7A; and

FIGS. 8A to 8F are diagrams illustrating a manufacturing process of a semiconductor package according to an example embodiment.

### DETAILED DESCRIPTION

Hereinafter, with reference to the accompanying drawings, example embodiments of the present inventive concept will be described as follows.

Unless otherwise specified, in this specification, terms such as ‘upper’, ‘upper surface’, ‘lower’, ‘lower surface’, ‘side’ and the like are based on the drawings, and actually, may vary depending on the direction in which the components are disposed. Unless otherwise specified, spatially relative terms, such as “beneath,” “below,” “lower,” “above,” “upper,” “top,” “bottom,” “front,” “rear,” “edge”, “side” and the like, may be used herein for ease of description to describe one element's or feature's relationship to another element(s) or feature(s) such as illustrated in the figures, for example. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Items described in the singular herein may be provided in plural, as can be seen, for example, in the drawings. Thus, the description of a single item that is provided in plural should be understood to be applicable to the remaining plurality of items unless context indicates otherwise.

Additionally, ordinal numbers such as “first,” “second,” “third,” etc. may be used as labels for specific elements, steps, directions, etc. to distinguish various elements, steps, directions, etc. from each other. Terms that are not described using “first,” “second,” etc. in the specification may still be referred to as “first” or “second” in the claims. Additionally, terms (for example, “first” in a particular claim) referenced by a particular ordinal number may be described elsewhere with a different ordinal number (for example, “second” in the specification or another claim).

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

In the drawings and the description of embodiments of the invention, like features and elements have been identified by the same or similar reference numerals and/or letters, and duplicate descriptions may be omitted for the purpose of simplicity and clarity.

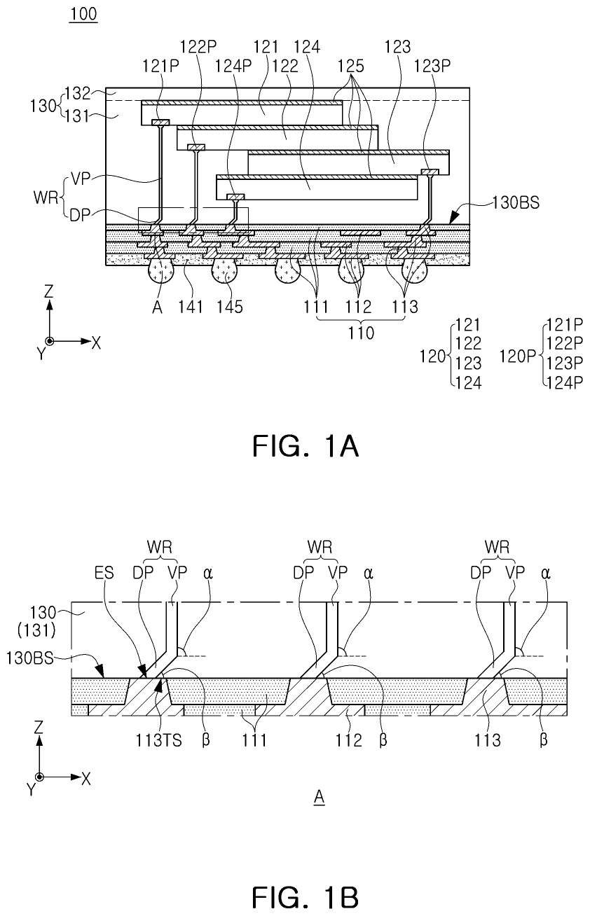

FIG. 1A is a cross-sectional view of a semiconductor package 100 according to an example embodiment, and FIG. 1B is a partially enlarged view of area ‘A’ of FIG. 1A.

Referring to FIGS. 1A and 1B, the semiconductor package 100 of the example embodiment may include a redistribution structure 110, a plurality of semiconductor chips 120, a molded layer 130, and connection wires WR.

The redistribution structure 110 is disposed below the molded layer 130 and may be configured to redistribute (or re-map) electrical connections from the connection wires WR to connection bumps 145 and/or electrical connections between the plurality of semiconductor chips 120. The redistribution structure 110 may include an insulating layer 111, redistribution layers 112, and redistribution vias 113.

As used herein, components described as being “electrically connected” are configured such that an electrical signal or power can be transferred from one component to the other (although such electrical signal or power may be attenuated in strength as it is transferred and may be selectively transferred). For example, electrically connected components may include components electrically connected through one or more of conductors (e.g., wires, pads, internal electrical lines, through vias, etc.) and active elements such as transistors or diodes.

The insulating layer 111 may include an insulating resin. The insulating resin may include thermosetting resins such as epoxy resins, thermoplastic resins such as polyimide, or these resins impregnated with inorganic fillers and/or glass fibers. For example, the insulating layer 111 may be formed of or include a material such as prepreg, Ajinomoto Build-up Film (ABF), Fire Retardent-4 (FR-4), Bismaleimide Triazine (BT), or the like. Depending on some example embodiments, the insulating layer 111 may include a photosensitive resin such as Photo-Imageable Dielectric (PID). For example, the insulating layer 111 may be formed of or include photosensitive polyimide, polybenzoxazole (PBO), phenol polymer, benzocyclobutene polymer, or the like. As shown in the drawing, the insulating layer 111 may be a composite layer of a plurality of insulating layers stacked in a vertical direction (Z-axis direction). Depending on the process, the boundaries between the plurality of insulating layers 111 may not be clearly distinguished. For example, the boundaries between the plurality of insulating layers 111 may not be clearly distinguishable in a metrology technique image.

The redistribution layers 112 are disposed below at least a portion of the insulating layer 111 and may redistribute electrical connections from the ends of the connection wires WR. The redistribution layers 112 may include a metal material containing, for example, copper (Cu), aluminum (Al), silver (Ag), tin (Sn), gold (Au), nickel (Ni), lead (Pb), titanium (Ti), or alloys thereof. The redistribution layers 112 may include, for example, a ground pattern, a power pattern, and a signal pattern. The signal pattern may provide an electrical path through which various signals such as data signals as well as ground signals and power signals are transmitted/received. Though the number of the redistribution layers 112 in the drawing is three, the invention is not limited thereto.

Redistribution vias 113 may extend between the redistribution layers 112 through the corresponding insulating layer 111. Each of the redistribution vias 113 may electrically connect the redistribution layers 112 located on different levels, or may electrically connect the redistribution layers 112 and the connection wires WR. The redistribution vias 113 may include a metal material containing, for example, copper (Cu), aluminum (Al), silver (Ag), tin (Sn), gold (Au), nickel (Ni), lead (Pb), titanium (Ti), or alloys thereof. The redistribution vias 113 may be conductive metal material that fills via holes which are formed through the insulating layer 111. The metal material may fully fill the via holes or may be conformally formed along the inner walls of the via holes. The redistribution vias 113 may be integrated with the corresponding redistribution layers 112, but the invention is not limited thereto.

The redistribution structure 110 may be substituted by a package substrate or an interposer, which may perform the function of redistribution of electrical connections. For example, the redistribution structure 110 may be a printed circuit board (PCB), a silicon interposer or combination thereof. The redistribution structure 110 may be a package substrate.

The connection bumps 145 may be disposed below the redistribution structure 110. The connection bumps 145 may be electrically connected to the chip stack (the plurality of semiconductor chips) 120 through the redistribution layers 112. The connection bumps 145 may electrically connect the semiconductor package 100 to an external device such as a module substrate or a main board. For example, the connection bumps 145 may have a flip-chip connection structure with a grid array such as a ball grid array. The connection bumps 145 may have a spherical or oval shape formed of a low melting point metal, for example, tin (Sn), indium (In), bismuth (Bi), antimony (Sb), copper (Cu), silver (Ag), zinc (Zn), lead (Pb), or alloys thereof (for example, Sn—Ag—Cu), or the like. In some embodiments, an UBM (under-bump metal, under-bump metallization or under-bump-metallurgy) layer may be further formed between the connection bumps 145 and the redistribution layers 112.

The connection bumps 145 may be solder balls or conductive pillars, e.g.,. The connection bumps 145 may be connection terminals and such connection terminals may also be formed as external pads, conductive tabs, etc. rather than connection bumps. Depending on some example embodiments, the protective layer 141 may be

disposed below the redistribution structure 110. The protective layer 141 may protect the lowermost redistribution layer 112 from external physical and chemical damage. The protective layer 141 may include or be formed of an insulating material. For example, the protective layer 141 may be formed of solder resist (PSR) by using an exposure process.

The plurality of semiconductor chips 120 may be a semiconductor wafer on which an integrated circuit (IC) is formed. In some embodiments, the plurality of semiconductor chips 120 may be obtained by dividing (e.g., cutting) a semiconductor wafer on which a plurality of integrated circuits is formed. Semiconductor wafers may include, for example, a semiconductor substrate formed of a crystalline semiconductor material such as silicon, germanium, or semiconductor compounds. The semiconductor compounds may be silicon carbide (SiC), gallium arsenide (GaAs), indium arsenide (InAs), or indium phosphide (InP).

The plurality of semiconductor chips 120 may be bare semiconductor chips without separate bumps or wiring layers, but are not limited thereto and may be packaged type semiconductor chips.

For example, the plurality of semiconductor chips 120 may include conductive pads (e.g., connection pads 120P) through which an electrical signal and/or power are transferred from and/or to the connection bumps 145. The conductive pads may be exposed by an insulating layer such as a passivation layer. The conductive pads may be electrically connected to integrated circuits formed in the semiconductor chips 120.

In some embodiments, the plurality of semiconductor chips 120 may further include additional structure on the conductive pad. The additional structure may be formed by a wafer-level packaging process. The additional structure may include additional conductive pads electrically connected to integrated circuits formed in the semiconductor chips 120. The additional conductive pads may be electrically connected to the connection bumps 145. The additional connection pads may be the connection pads 120P.

The plurality of semiconductor chips 120 may include a logic chip, such as a central processor (CPU), a graphics processor (GPU), a field programmable gate array (FPGA), an application processor (AP), a digital signal processor, a cryptographic processor, a microprocessor, a microcontroller, an analog-to-digital converter, an application-specific IC (ASIC) or the like. The plurality of semiconductor chips 120 may include or be a memory chip that include a volatile memory, such as a dynamic RAM (DRAM) and a static RAM (SRAM). The plurality of semiconductor chips 120 may include or be a non-volatile memory, such as a phase change RAM (PRAM), a magnetic RAM (MRAM), a resistive RAM (RRAM) and a flash memory.

The plurality of semiconductor chips 120 may be arranged such that the connection pads 120P face the redistribution structure 110. The plurality of semiconductor chips 120 may have a front surface on which the connection pads 120P are disposed and a rear surface opposite to the front surface, and may be stacked so that the front surface faces the redistribution structure 110. As shown in the drawing, the plurality of semiconductor chips 120 may be stacked in a shifted form (or in a step-like manner) so that each connection pad 120P is exposed downwards in overhang regions. An adhesive film layer 125 may be disposed on the rear surface of each of the plurality of semiconductor chips 120. The adhesive film layer 125 may include or be die attach film (DAF).

For example, the plurality of semiconductor chips 120 may include a first semiconductor chip 121, a second semiconductor chip 122, a third semiconductor chip 123, and a fourth semiconductor chip 124 sequentially stacked from the top. The first semiconductor chip 121 includes first connection pads 121P, the second semiconductor chip 122 includes second connection pads 122P, the third semiconductor chip 123 includes third connection pads 123P, and the fourth semiconductor chip 124 may include fourth connection pads 124P.

Respective shift directions of the first semiconductor chip 121, the second semiconductor chip 122, the third semiconductor chip 123, and the fourth semiconductor chip 124, and respective positions of the first connection pads 121P, the second connection pads 122P, the third connection pads 123P, and the fourth connection pads 124P, may be modified into various forms different from those illustrated in the drawing. For example, the manner of stacking of the plurality of semiconductor chips 120 may be modified from that shown in the drawing such that the overhang regions are arranged differently.

The molded layer 130 may seal (encapsulate) the plurality of semiconductor chips 120. The molded layer 130 may fill the space between the redistribution structure 110 and the plurality of semiconductor chips 120. The molded layer 130 may include a lower portion 131 covering respective side surfaces of the plurality of semiconductor chips 120 and a front surface of a lowermost semiconductor chip among the plurality of semiconductor chips 120. For example, the lower portion 131 may cover covering each side of the plurality of semiconductor chips 120 and the front surface of the lowest semiconductor chip (for example, the fourth semiconductor chip 124) among the plurality of semiconductor chips 120, and an upper portion 132 covering the rear surface of the uppermost semiconductor chip (for example, the first semiconductor chip 121) among the plurality of semiconductor chips 120. The upper portion 132 may protect the uppermost semiconductor chip (for example, the first semiconductor chip 121) from physical and chemical damage. The molded layer 130 may include an insulating resin containing an inorganic filler, such as ABF or Epoxy Molding Compound (EMC).

Depending on the process, the boundary between the lower portion 131 and the upper portion 132 may not be clearly distinguishable. For example, the lower portion 131 and the upper portion 132 may be a single continuous homogenous layer formed integrally by a single process. The lower portion 131 and the upper portion 132 of the molded layer 130 may include the same material, but the invention is not limited thereto.

The connection wires WR may extend from the connection pads 120P of each of the plurality of semiconductor chips 120 to the bottom surface 130BS of the molded layer 130. Each of the connection wires WR extend within the molded layer 130 and may electrically connect one of the connection pad 120P and a corresponding one of the redistribution vias 113 to each other. For example, the plurality of connection wires WR may electrically connect the connection pads and the redistribution vias in a one-to-one manner. The connection wires WR may include gold (Au), silver (Ag), lead (Pb), aluminum (Al), copper (Cu), or alloys thereof, but the invention is not limited thereto. The connection wires WR may be bonding wires.

Each of the connection wires WR may include a vertical portion VP and a diagonal portion DP. In this specification, the vertical portion VP and the diagonal portion DP may be referred to as ‘first portion’ and ‘second portion’, respectively. The vertical portion VP may contact the connection pads 120P and may extend in the vertical direction (Z-axis direction) toward the redistribution structure 110 or a direction toward the bottom surface 130BS of the molded layer 130. The diagonal portion DP may extend diagonally between the vertical portion VP and the corresponding redistribution via 113 such that an end of the diagonal portion DP is exposed to the bottom surface 130BS of the molded layer 130. The end of the diagonal portion DP may be in contact with the corresponding redistribution via 113.

For example, the connection wires WR may be a kind of vertical bonding wires, and may not include (or may have a relatively limited amount of) a curved or arched shape such that the electrical path between the substrate and the connection pad may be reduced compared to loop-anchored wires. Each of the connection wires WR may be divided into long and short parts. The wire length of the long part may be greater than that of the short part. The long part of the vertical bonding wire may vertically and linearly extend in a straight path from the semiconductor chip toward the redistribution structure 110. In a wire bonding process, the long part may terminate at its connection to the short part. The short part may linearly extend in an inclined direction between the long part and the redistribution structure 110. The long part may include a bonding part contacting the connection pad. The long and short parts may be the vertical portion VP and the diagonal portion DP, respectively.

According to example embodiments, the diagonal portion DP is extended to have a predetermined inclination angle with respect to the bottom surface 130BS of the molded layer 130. Due to the inclination, the area of the connection wires WR exposed to the bottom surface 130BS of the molded layer 130 may be increased, when compared to a connection wire having only a vertical portion. As a result, the connection reliability of the connection wires WR and the redistribution vias 113 may be improved.

In some embodiments, the vertical portion VP may extend from the connection pads 120P at a first inclination angle α with respect to the bottom surface 130BS of the molded layer 130. The diagonal portion DP may extend from the vertical portion VP to a second inclination angle B (e.g., an acute angle) that is smaller than the first inclination angle α with respect to the bottom surface 130BS of the molded layer 130.

The vertical portion VP may be extended such that the first inclination angle α may be constant or change continuously. In some exemplary embodiments, the first and second portions may be formed such that the first inclination angle α may be constant, and the second inclination angle β may be constant or change continuously.

The diagonal portion DP may be extended such that the second inclination angle β may be constant or change continuously. The vertical portion VP and the diagonal portion DP may be distinguished by a point at which the inclination angle with respect to the bottom surface 130BS of the molded layer 130 changes discontinuously. For example, the first and second inclination angles may change continuously (curved) such that the first and second portions extend smoothly and without abrupt shifts in their extending direction (e.g., the angles is gradually altered as the wire is extended, rather than having sudden changes), and the first and second portions may be differentiated by a point where the inclination angle of the connection wire changes abruptly.

In an exemplary embodiment, the first inclination angle α may be 90° or close to 90°. For example. the first inclination angle α may be an angle within a range of about 70° to about 90° (or a narrower range). The second inclination angle β may be an angle within a range of about 20° to about 80°. For example, the second inclination angle β may range (or may be an angle within one of the ranges) from about 20° to about 70°, from about 20° to about 60°, from about 20° to about 50°, or from about 20° to about 45°.

However, the second inclination angle β is not limited to the above-mentioned numerical range. For example, the second inclination angle β may be determined at an appropriate value by considering the alignment margin (or tolerance) between the redistribution via 113 and the connection wire WR.

The diagonal portions DP each may have an end surface ES in contact with a corresponding one of redistribution vias 113. The bottom surface 130BS of the molded layer 130 and the end surface ES of the diagonal portion DP may form the same surface. The bottom surface 130BS of the molded layer 130 and the end surface ES of the diagonal portion DP may be coplanar. Each of the redistribution vias 113 may have a top surface 113TS in contact with the end surface ES of the diagonal portion DP. A first boundary between the top surface 113TS of each of the redistribution vias 113 and the end surface ES of the diagonal portion DP may be at substantially the same level as the second boundary between the bottom surface 130BS of the molded layer 130 and the upper surface of the insulating layer 111.

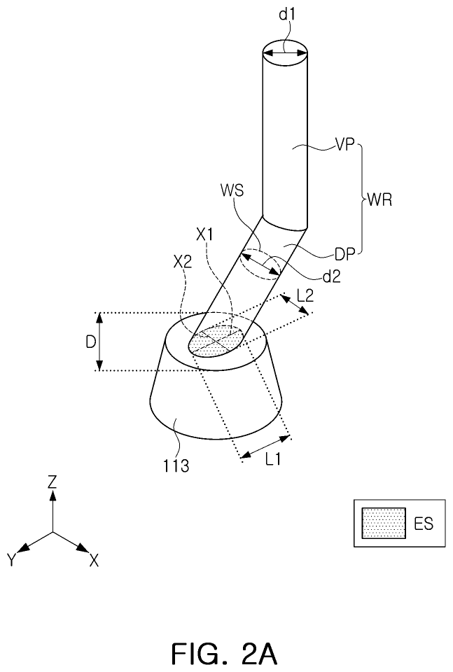

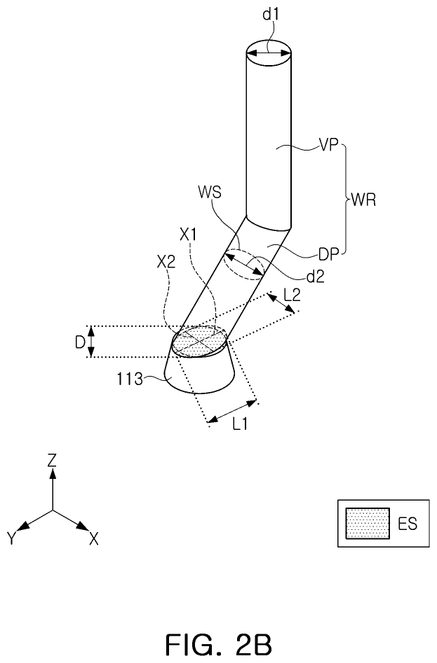

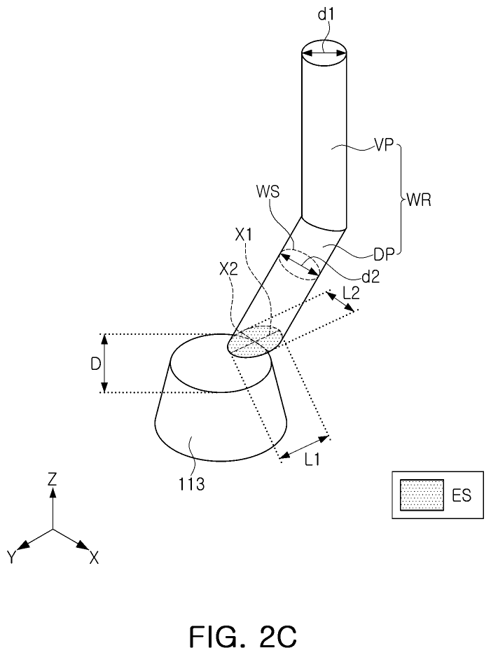

Hereinafter, the connection structure of the redistribution via 113 and the connection wire WR will be described with reference to FIGS. 2A to 2C.

FIGS. 2A to 2C are perspective views illustrating the end surface ES of the connection wire WR in contact with the redistribution via 113.

Referring to FIGS. 2A to 2C, on a plane (X-Y plane), the end surface ES of the diagonal portion DP may have an oval shape with a major axis X1 and a minor axis X2.

The length L1 of the oval-shaped major axis X1 may be understood as the major axis of the diagonal portion DP exposed to the bottom surface 130BS of the molded layer 130. The length L1 of the oval-shaped (e.g., elliptical) major axis X1 may be larger than a first diameter d1 of the vertical portion VP of the connection wire WF and a second diameter d2 of the diagonal portion DP of the connection wire WF.

The diameter of the connection wire WF may refer to the dimension of the wire in the direction perpendicular to the extending direction of the wire (e.g., in the general direction of current flow that the wire provides). The diameter may be a dimension of the wire in a direction perpendicular to the longitudinal surface. it should be appreciated that the measurement of the diameter may not consider the shape of the wire tip when formed as a bulge (e.g., the bonding part described herein) which is typically formed during a process to connect the wire to the connection pad 120P by using a capillary and/or ultrasonic energy. The shape of the bulged wire tip bonded to the pad may be a ball shape, a stitch shape, an elongated shape or a rectangular shape.

The length L2 of the oval-shaped minor axis X2 may be understood as a minimum axis of the diagonal portion DP exposed to the bottom surface 130BS of the molded layer 130. For example, the length L2 of the minor axis X2 of an elliptical shape may be substantially equal to the first diameter d1 of the vertical portion VP of the connection wire WF and/or the second diameter d2 of the diagonal portion DP of the connection wire WF.

For example, the first diameter d1 of the vertical portion VP and the second diameter d2 of the diagonal portion DP may range (or may be a dimension within a range) from about 20 μm to about 30 μm. The first diameter d1 of the vertical portion VP and the second diameter d2 of the diagonal portion DP may be equal to each other.

Referring to FIG. 2A, in an example embodiment, when the top surface of the redistribution via 113 is circular, the top surface of the redistribution via 113 may be formed to have a larger planar area than the end surface ES of the diagonal portion DP. For example, the maximum width D of the top surface of the redistribution via 113 may be greater than the length L1 of the oval-shaped major axis X1 and the length L2 of the oval-shaped minor axis X2 in a plan view.

Referring to FIG. 2B, in an example embodiment, when the top surface of the redistribution via 113 is circular, the maximum width D of the top surface of the redistribution via 113 may be at least greater than the length L2 of the elliptical minor axis (oval-shaped minor axis or minimum axis) X2 in the plan view. For example, the maximum width D of the top surface of the redistribution via 113 may be smaller than the length L1 of the oval-shaped major axis X1 and larger than the length L2 of the oval-shaped minor axis X2.

Referring to FIG. 2C, in an example embodiment, the top surface of the redistribution via 113 and the end surface ES of the diagonal portion DP may partially contact each other.

Referring to FIGS. 2A to 2C, a planar area of the end surface ES of the diagonal portion DP in a plan view is larger than that of the cross-sectional surface WS of the connection wire WR in another view. For example, the cross-sectional surface WS may be defined by the first diameter d1 or the second diameter d2. Thus, the alignment margin of the redistribution via 113 may be secured and connection reliability may be improved.

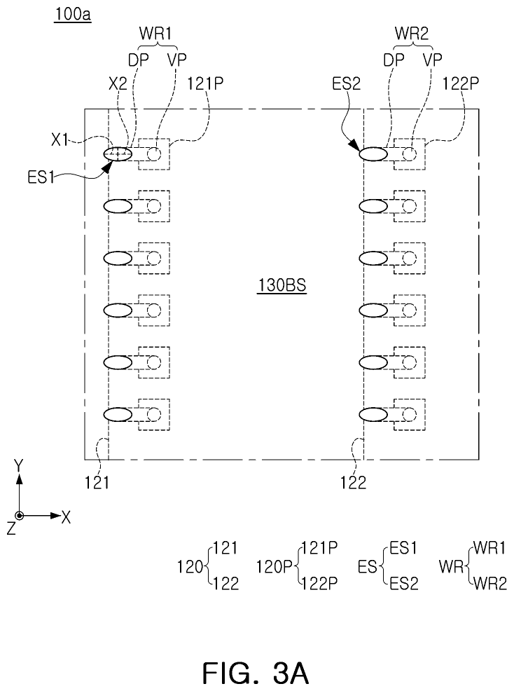

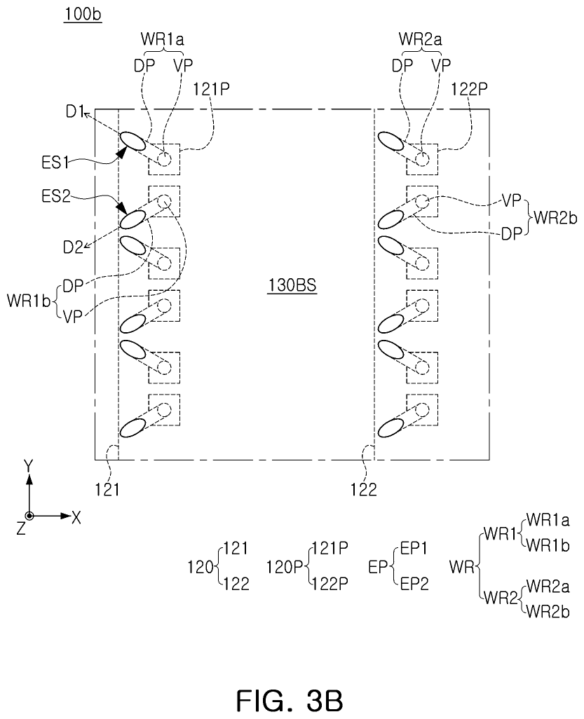

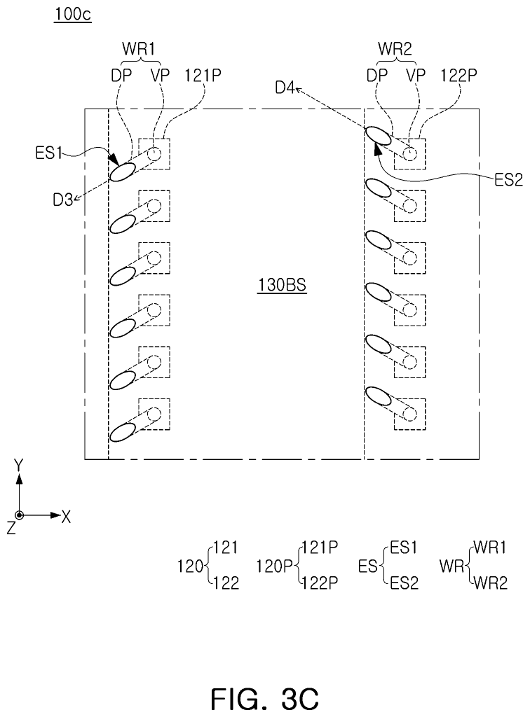

Hereinafter, with reference to FIGS. 3A to 3C, the arrangement of the end surfaces ES of the connection wires WR will be described.

FIGS. 3A to 3C are diagrams illustrating semiconductor packages according to an embodiment and its illustrative modifications. FIGS. 3A to 3C partially illustrate the bottom surface 130BS of the molded layer to explain the arrangement of the end surfaces ES of the connection wires WR. Each of the plurality of semiconductor chips may include a set of connection pads provided along a first edge of each of the first semiconductor chips as shown in the drawings.

Referring to FIG. 3A, in the semiconductor package 100a of an embodiment, the diagonal portions DP of the connection wires WR may be exposed to the bottom surface 130BS of the molded layer, respectively. The end surface ES of the diagonal portion DP may have an oval shape with a major axis X1 and a minor axis X2. The length of the major axis X1 of the end surface ES may be determined by the inclination angle of the diagonal portion DP with respect to the bottom surface 130BS of the molded layer 130. For example, the greater the length of the major axis X1, the greater the inclination angle of the diagonal portion DP with respect to the bottom surface 130BS of the molded layer 130. As the inclination angle of the diagonal portion DP decreases, the length of the major axis X1 of the end surface ES may increase. The contact margin of the connection wire WR may be improved by the oval shape of the end surface ES.

End surfaces ES of the connection wires WR may be arranged on the corresponding connection pads 120P. For example, the connection wires WR may include a first connection wire WR1 connected to the first connection pads 121P and a second connection wire WR2 connected to the second connection pads 122P. The first end surfaces ES1 of the first connection wire WR1 are arranged on the corresponding first connection pads 121P, and the second end surfaces ES2 of the second connection wire WR2 may be arranged on the corresponding second connection pads 122P. In a plan view, the diagonal portions DP may extend to positions where each end surface ES does not overlap the corresponding connection pads 120P. In some embodiments, in a plan view, the end surfaces ES may at least partially overlap the corresponding connection pads 120P.

The connection pad 120P may have a pad surface in a plan view (as viewed from the vertical direction) and pad edges defining the pad surface. Each pair of the edges may share one of pad vertices. The pad surface may be polygon-surface. For example, the polygon-surface may be square-shaped. As shown in FIG. 3A, in a plan view, each of the major axis X1 of a group of connection wires WR1 and WR2 may be aligned to a horizontal direction (X-direction), and the horizontal direction may be parallel to at least one of the corresponding pad edges. In this example embodiment, all of the end surfaces ES adjacent to each other may have the same alignment directions of the major axis X1. For example, all of the end surfaces ES (or the axes X2) may extend in the same direction (X-direction) as shown in FIG. 3A.

In other example embodiments, at least some of the end surfaces ES adjacent to each other may have different alignment directions of the major axis X1 (see FIGS. 3B and 3C). For example, at least some of the end surfaces ES (or the axes X2) may extend in a different direction from the others, when compared to other end surfaces ES (or the axes X2).

In some embodiments, the pad vertices of the connection pads RP may be rounded corners of polygon-shaped pads (e.g., square-shaped pads) in a plan view. The rounded vertices may be unintentional, but acceptable variations that may occur due to conventional manufacturing processes.

As described previously, terms as used herein when describing features of orientation, layout, location, shapes, sizes, compositions, amounts, or other measures do not necessarily mean features defined by the dictionary meaning of the terms, but are intended to encompass acceptable variations that may occur, for example, due to manufacturing processes or to encompass typically acceptable tolerances of conventional manufacturing process technology. For example, “square” may encompass a square having rounded vertices as a typically acceptable variation in industry. The term “substantially” may be used herein to emphasize this meaning. In this context, terms such as “same,” “equal,” “planar,” “coplanar,” “parallel,” “perpendicular,” “vertical,” “straight,” “diagonal,” “constant” and the like as used herein may encompass such variations or tolerances that may be resulted from conventional manufacturing processes.

A plurality of connection wires may include a pair of connection wires (e.g., a pair WR1a and WR1b in FIG. 3B, or a pair WR1 and WR1 in FIG. 3C) adjacent to each other, and the pair of connection wires may have major axes of the oval shape respectively. The major axes may extend in different directions from each other in a plan view.

For example, referring to FIG. 3B, the connection wires WR connected to one semiconductor chip may be formed to have two or more alignment directions. For example, in the semiconductor package 100b of the illustrative variant, each of the major axis of the first group of connection wires WR1a and WR2a may be aligned to a first horizontal direction D1, and the horizontal direction D1 may have an angle to one of the corresponding pad edges in a plan view.

The first connection wires WR1 may include a first group of first connection wires WR1a having a first end surface ES1 whose major axis is aligned in the first horizontal direction D1, and a second group of first connection wires WR1b having a second end surface ES2 whose major axis is aligned in a second horizontal direction D2 intersecting the first horizontal direction D1. The second connection wires WR2 may include a first group of second connection wires WR2a having a first end surface ES1 whose major axis is aligned in the first horizontal direction D1, and a second group of second connection wires WR2b having a second end surface ES2 whose major axis is aligned in a second horizontal direction D2 intersecting the first horizontal direction D1.

Referring to FIG. 3C, connection wires WR respectively connected to the plurality of semiconductor chips 120 may be formed to have different alignment directions. For example, in the semiconductor package 100c of FIG. 3C, the first connection wire WR1 has a first end surface ES1 whose major axis is aligned in the third horizontal direction D3, and the second connection wire WR2 may have a second end surface ES2 whose major axis is aligned in the fourth horizontal direction D4.

In this manner, a pattern may be formed such that the position of the connection wires WR may be confirmed or formed to be used as an alignment standard, defect detection standard or the like, by using the alignment direction of the oval end surface ES of the connection wires WR.

For example, by utilizing the manner of disposition of the wires illustrated in FIGS. 3A top 3C, a specific pattern of an array of the end surfaces ES may be formed, and may be used as an alignment key during the manufacturing process of the semiconductor package.

In some embodiments, to detect defects such as wire mixing after the molding process, it may be checked whether the end surfaces ES of the connection wires WR maintain a designed alignment direction or a desired shape of the pattern. For example, a pattern of an array of the end surfaces ES may be analyzed for the purpose of detection of defects (wire mixing or wire sweeping) which result from the manufacturing process of the semiconductor package. To detect the defect, it may be checked whether the alignment direction (or shape) of the end surfaces ES of the connection wires WR (or the array pattern) maintain the desired configuration.

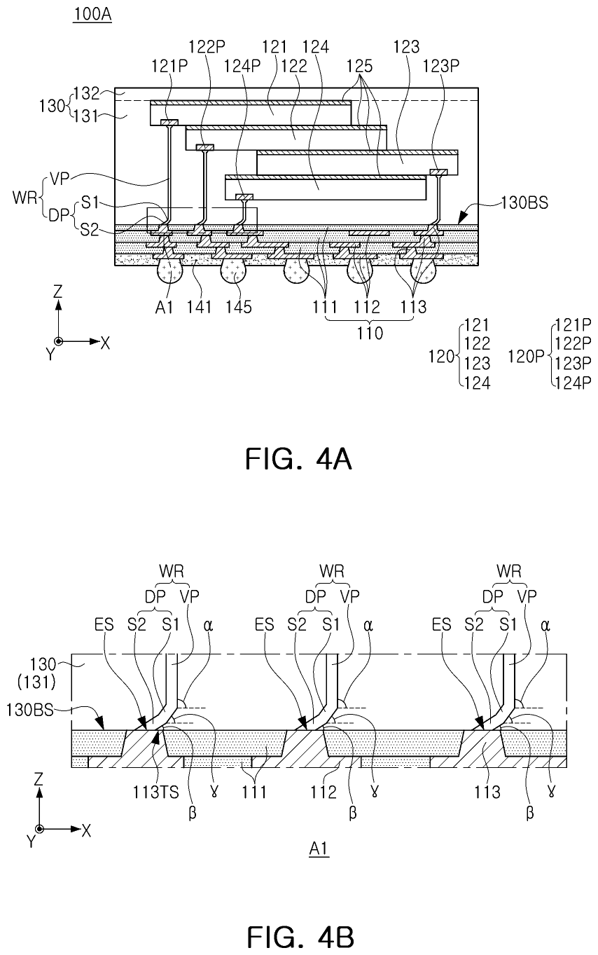

FIG. 4A is a cross-sectional view of a semiconductor package 100A according to an example embodiment, and FIG. 4B is a partial enlarged view of the ‘A1’ area of FIG. 4A.

Referring to FIGS. 4A and 4B, the semiconductor package 100A of the example embodiment may have the same or similar features as those described with reference to FIGS. 1A to 3C, except that the diagonal portion DP of the connection wires WR comprises two or more sub-segments with different inclination angles. The connection wires WR of the example embodiment may include a vertical portion VP, a first sub-segment S1, and a second sub-segment S3. The vertical portion VP may extend at a first inclination angle α with respect to the bottom surface 130BS of the molded layer 130. The first sub-segment S1 may extend from the vertical portion VP at a third inclination angle γ with respect to the bottom surface 130BS of the molded layer 130. The second sub-segment S2 may extend from the first sub-segment S1 at a second inclination angle B with respect to the bottom surface 130BS of the molded layer 130. The third inclination angle γ may range (or may be an angle within a range) from about 20° to about 80. The second inclination angle β may be smaller than the first inclination angle α and the third inclination angle γ, and the third inclination angle γ may be smaller than the first inclination angle α, though the invention is not limited to the relationship between the inclination angles. The first sub-segment S1 and the second sub-segment S3 may be distinguished by a point at which the inclination angle with respect to the bottom surface 130BS of the molded layer 130 changes discontinuously.

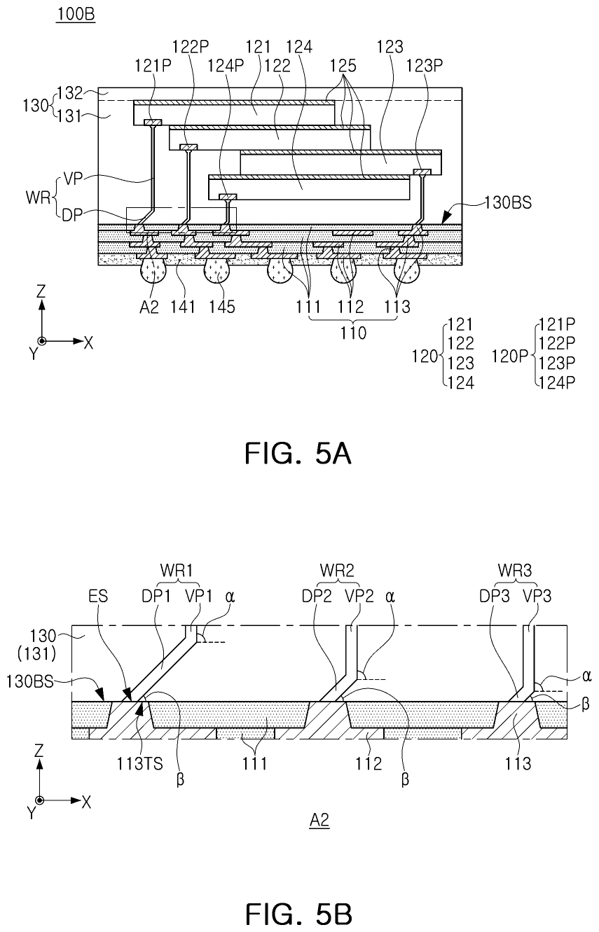

FIG. 5A is a cross-sectional view of a semiconductor package 100B according to an example embodiment, and FIG. 5B is a partial enlarged view of area ‘A2’ of FIG. 5A.

Referring to FIGS. 5A and 5B, the semiconductor package 100B of the example embodiment may have the same or similar features as those described with reference to FIGS. 1A to 4C, except that the diagonal portions DP of at least some of the connection wires WR have different lengths. The connection wires WR of the example embodiment may include diagonal portions DP having different extension lengths. The first diagonal portion DP1 of the first connection wire WR1, the second diagonal portion DP2 of the second connection wire WR2, and the third diagonal portion DP3 of the third connection wire WR3 may have different lengths. For example, the first diagonal portion DP1 has a first length in its extending direction, the second diagonal portion DP2 has a second length in its extending direction shorter than the first length, and the third diagonal portion DP3 may have a third length in its extension direction shorter than the second length.

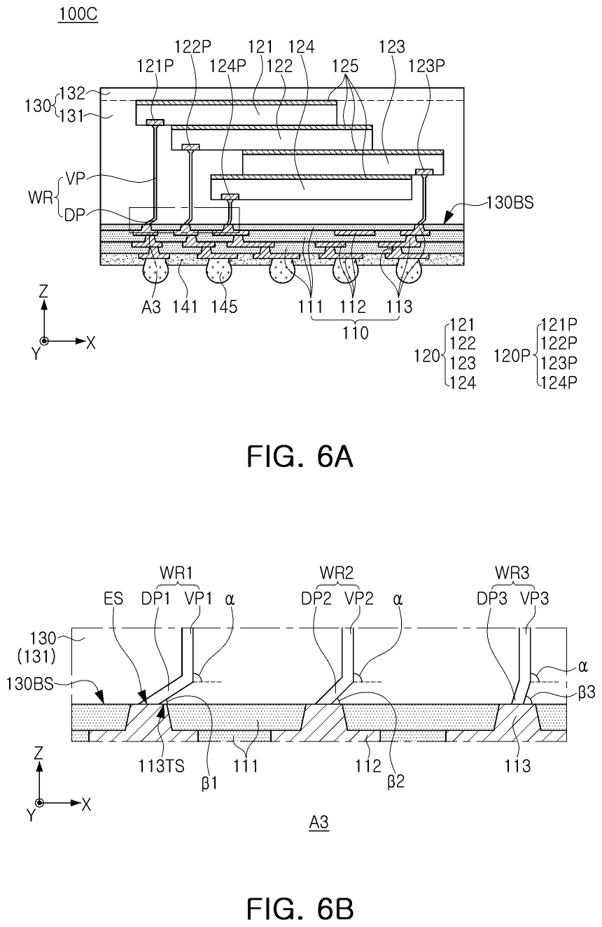

FIG. 6A is a cross-sectional view of a semiconductor package 100C according to an example embodiment, and FIG. 6B is a partial enlarged view of area ‘A3’ of FIG. 6A.

Referring to FIGS. 6A and 6B, the semiconductor package 100C of an example embodiment may have the same or similar features as those described with reference to FIGS. 1A to 5C, except that the diagonal portions DP of at least some of the connection wires WR have different inclination angles. The connection wires WR of the example embodiment may include diagonal portions DP having different inclination angles with respect to the bottom surface 130BS of the molded layer 130. The first connection wire WR1 may include a first diagonal portion DP1 having a fourth inclination angle β1 with respect to the bottom surface 130BS of the molded layer 130. The second connection wire WR2 may include a second diagonal portion DP2 having a fifth inclination angle β2 with respect to the bottom surface 130BS of the molded layer 130. The third connection wire WR3 may include a third diagonal portion DP3 having a sixth inclination angle β3 with respect to the bottom surface 130BS of the molded layer 130. The fourth inclination angle β1, the fifth inclination angle β2, and the sixth inclination angle β3 may range (or may be an angle within a range) from about 20° to about 80°. For example, the fourth inclination angle β1, the fifth inclination angle β2, and the sixth inclination angle β3 may range (or may be an angle within one of the ranges) from about 20° to about 70°, from about 20° to about 60°, from about 20° to about 50°, or from about 20° to about 45°. However, the invention is not limited to the above-mentioned numerical ranges of the inclination angle (fourth inclination angle β1, the fifth inclination angle β2, and the sixth inclination angle β3). The inclination angles may be determined by considering the alignment margin of the redistribution via 113. In this manner, by variously modifying the inclination angle of the diagonal portion DS, the positions of the connection wires WR may be easily changed and the design freedom of the redistribution layer may be increased.

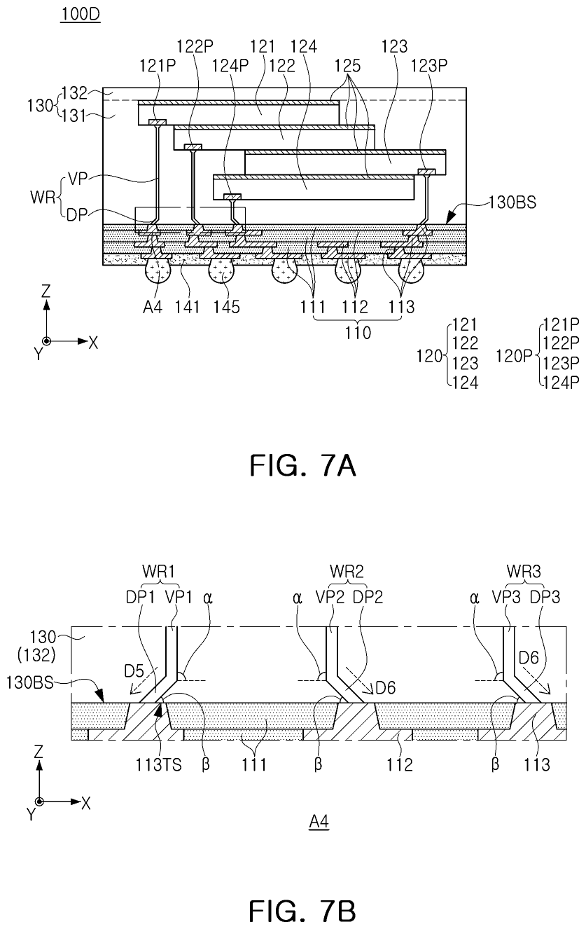

FIG. 7A is a cross-sectional view of a semiconductor package 100D according to an example embodiment, and FIG. 7B is a partial enlarged view of area ‘A4’ of FIG. 7A.

Referring to FIGS. 7A and 7B, the semiconductor package 100D of the example embodiment may have the same or similar features as those described with reference to FIGS. 1A to 6C, except that the diagonal portions DP of at least some of the connection wires WR extend in different diagonal directions. The connection wires WR of the example embodiment may include diagonal portions DP extending in different diagonal directions with respect to the vertical portion VP. The first connection wire WR1 may include a first diagonal portion DP1 extending in the first diagonal direction D5. The second connection wire WR2 may include a second diagonal portion DP2 extending in the second diagonal direction D6. The third connection wire WR3 may include a third diagonal portion DP3 extending in the second diagonal direction D6. In this embodiment, each of the oval end surfaces of the diagonal portion DS may be disposed differently and/or aligned differently from each other. For example, in a plan view, the oval end surface of the first connection wire WR1 may be aligned in the directions D5, and the oval end surfaces of the second and third connection wire WR2 and WR3 may be aligned in the directions D6, as shown in the example embodiments of FIGS. 3B and 3C. In this manner, by variously modifying the direction in which the diagonal portion DS extends, the positions of the connection wires WR may be easily changed and the degree of design freedom of the redistribution layer may be increased.

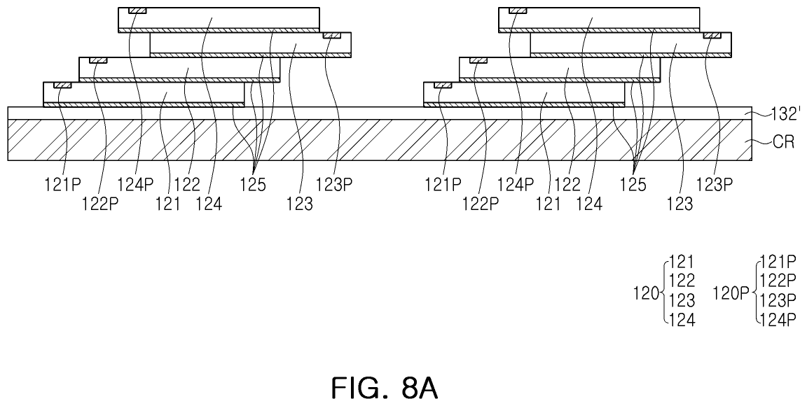

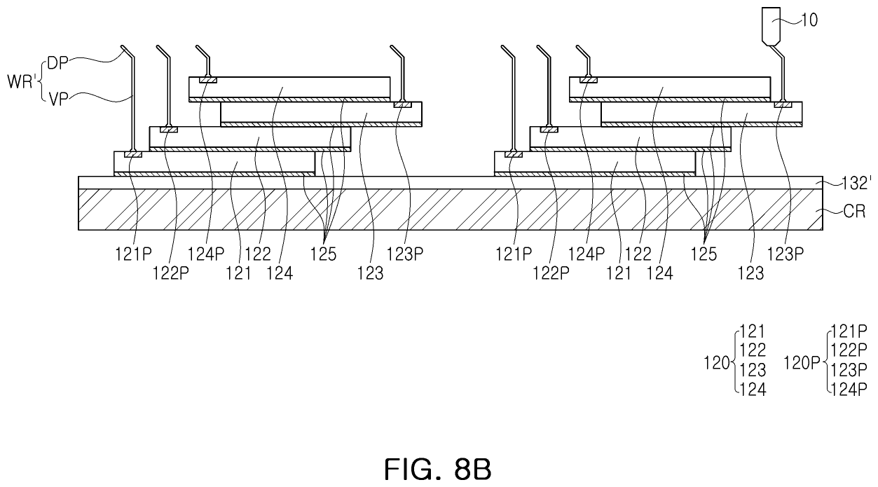

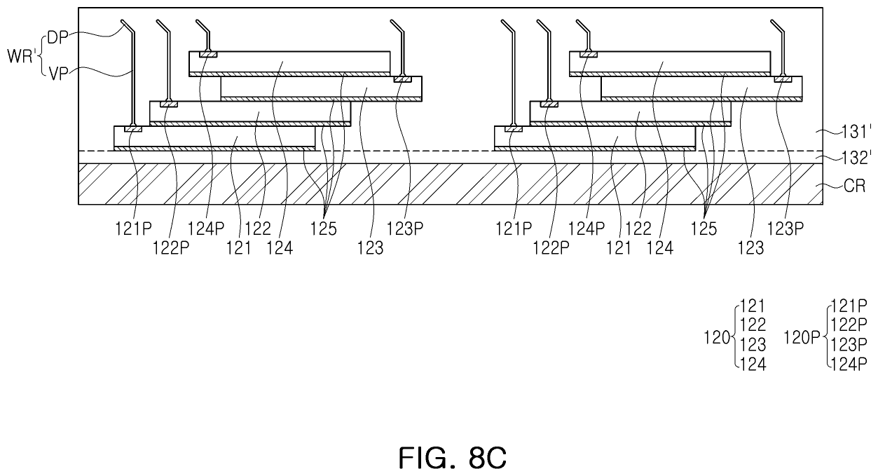

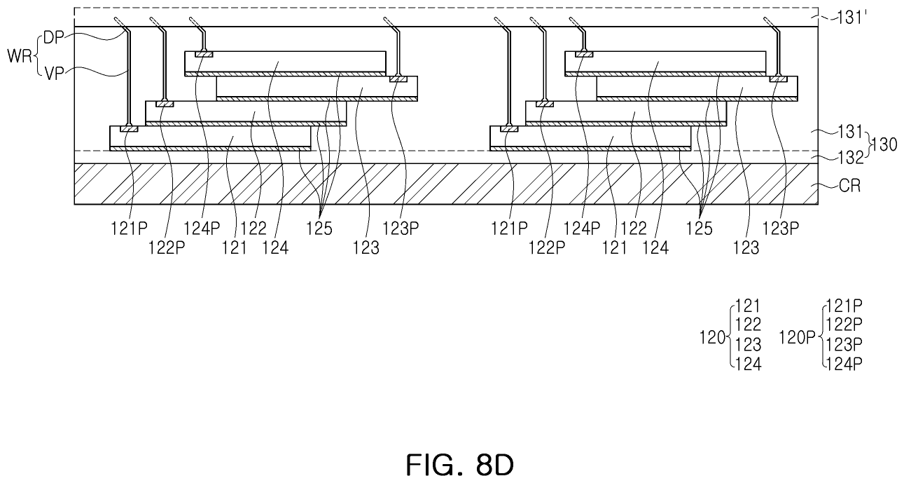

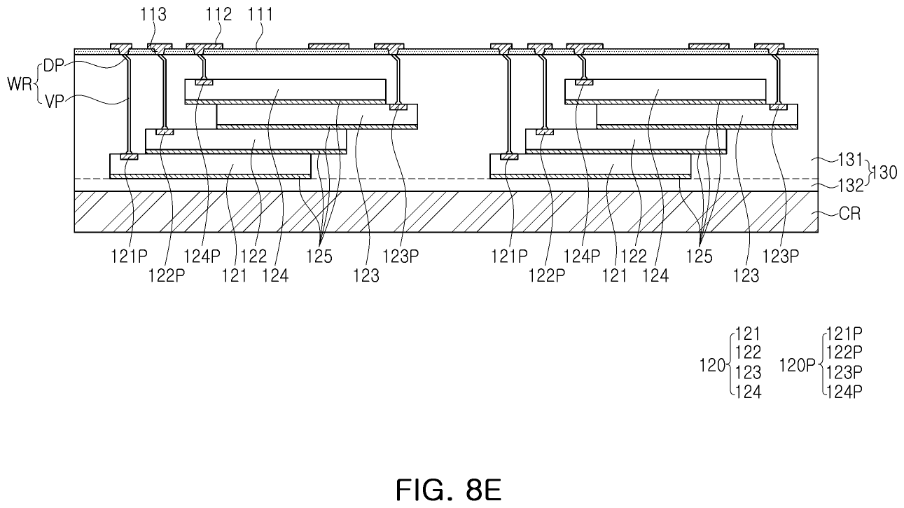

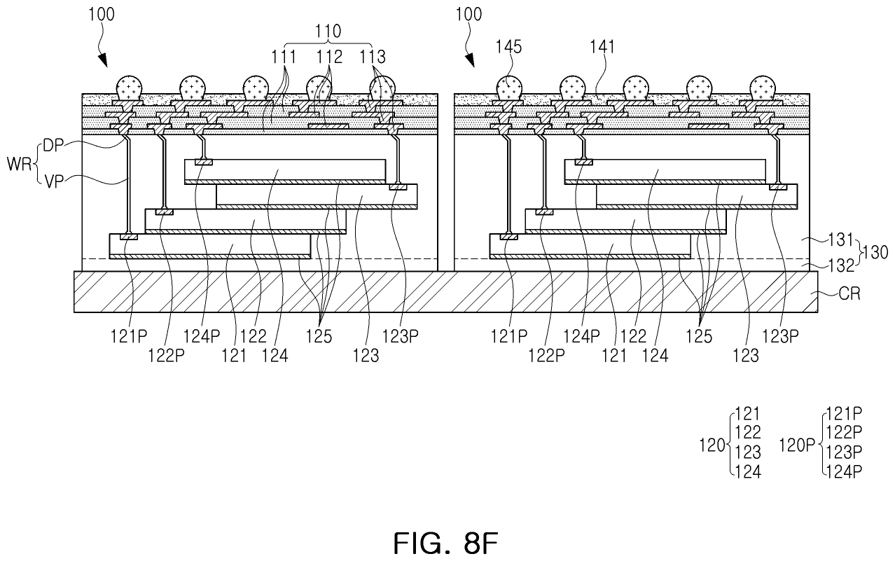

FIGS. 8A to 8F are diagrams illustrating the manufacturing process of the semiconductor package 100 according to an example embodiment.

Referring to FIG. 8A, a plurality of semiconductor chips 120 may be staked on the carrier substrate CR. The carrier substrate (CR) may be a temporary support substrate (e.g., a glass wafer, a curable resin layer, etc.). The plurality of semiconductor chips 120 may be stacked so that the connection pads 120P face upward. A plurality of semiconductor chips 120 may be attached to each other by an adhesive film layer 125. A first preliminary molded layer 132′ may be formed on the upper surface of the temporary carrier (carrier substrate) CR. The first preliminary molded layer 132′ may be formed by using, for example, EMC.

Referring to FIG. 8B, intermediate wires WR′ may be formed on the connection pads 120P. The intermediate wires WR′ may be formed by a wire bonding process using the capillary 10. The intermediate wires WR′ may be formed to include a vertical portion VP and a diagonal portion DP. The vertical portion VP may be formed to have an inclination angle from about 70° to about 90° with respect to the upper surface of the corresponding connection pad 120P. The diagonal portion DP may be formed to have an inclination angle ranging (or within a range) from about 20° to about 45° with respect to the upper surface of the corresponding connection pad 120P.

Referring to FIG. 8C, a second preliminary molded layer 131′ may be formed covering the intermediate wires WR′. The second preliminary molded layer 131′ may cover the side and front surfaces of each of the plurality of semiconductor chips 120. The second preliminary molded layer 131′ may be formed to completely cover the ends of the intermediate wires WR′. The second preliminary molded layer 131′ may be formed using the same insulating material as the first preliminary molded layer 132′.

Referring to FIG. 8D, a flat surface including the upper surface of the molded layer 130 and the upper surface of the connection wires WR may be formed. The molded layer 130 and the connection wires WR may be formed by partially removing the second preliminary molded layer 131′ and the preliminary wire WR′ through a grinding process or the like. The connection wires WR may have oval end surfaces exposed to the upper surface of the molded layer 130.

Referring to FIG. 8E, an insulating layer 111, redistribution layers 112, and redistribution vias 113 may be formed on the molded layer 130. The insulating layer 111 may be formed by sequentially applying and curing a photosensitive material, for example, PID. Redistribution layers 112 and redistribution vias 113 may be formed by performing an exposure process and a development process to form a via hole penetrating the insulating layer 111, and by forming a metal material on the insulating layer 111 using a plating process and patterning the metal material on the insulating layer 111. According to an example embodiment, the connection wires WR include a diagonal portion DP extending diagonally, thereby improving the alignment margin and connection reliability of the redistribution vias 113.

Referring to FIG. 8F, after the redistribution structure 110 and the connection bumps 145 are formed, the semiconductor packages 100 may be separated by performing a sawing process. The redistribution structure 110 may be formed by repeatedly performing different exposure processes, development processes, and plating processes. Connection bumps 145 may be formed within the opening of the protective layer 141. The connection bumps 145 may be formed by a solder ball attachment process.

As set forth above, according to example embodiments, a semiconductor package having improved reliability may be provided by introducing a connection wire having an increased area of contact with a redistribution via.

While example embodiments have been illustrated and described above, it will be apparent to those skilled in the art that modifications and variations could be made without departing from the scope of the present inventive concept as defined by the appended claims.

What is claimed is:

1. A semiconductor package comprising:
a package substrate including an insulating layer, redistribution layers below the insulating layer, and redistribution vias extending from the redistribution layers into the insulating layer;
a plurality of semiconductor chips respectively having a front surface on which connection pads are disposed and a rear surface opposite to the front surface, and stacked on the package substrate such that the front surface faces the package substrate;
a molded layer between the package substrate and the plurality of semiconductor chips;
a plurality of connection wires extending within the molded layer and electrically connecting to corresponding ones of the connection pads and corresponding ones of the redistribution vias; and
connection terminals electrically connected to the redistribution layers and disposed below the package substrate,
wherein each of the plurality of connection wires includes a first portion extending from a corresponding one of the connection pads at a first inclination angle with respect to a bottom surface of the molded layer, and a second portion extending from the first portion and having a second inclination angle with respect to the bottom surface of the molded layer,
wherein the second inclination angle is less than the first inclination angle, and
wherein each second portion of the plurality of connection wires has an end surface in contact with a corresponding one of the redistribution vias.

2. The semiconductor package of claim 1,
wherein each of the first portions has a corresponding first inclination angle that is constant or changes continuously,
wherein each of the second portions has a corresponding second inclination angle that is constant or changes continuously, and
wherein an inclination angle of each of the plurality of connection wires changes discontinuously between the first inclination angle and the second inclination angle.

3. The semiconductor package of claim 2,
wherein each of the first inclination angles falls within a range of 70° to 90°, and
wherein each of the second inclination angles falls within a range of 20° to 45°.

4. The semiconductor package of claim 1, wherein the bottom surface of the molded layer and the end surfaces of the second portions are coplanar.

5. The semiconductor package of claim 1, wherein a first boundary between a top surface of each of the redistribution vias and the corresponding one of the end surfaces of the second portions is at substantially the same level as a second boundary between the bottom surface of the molded layer and a top surface of the insulating layer.

6. The semiconductor package of claim 1,:
wherein, in a plan view, each of the end surfaces of the second portions has an oval shape with a major axis and a minimum axis, and
wherein, in the plan view, a top surface of each of the redistribution vias has a maximum width greater than the minimum axis of each of the oval shapes.

7. The semiconductor package of claim 6, wherein the maximum width of the top surface of each of the redistribution vias has greater length than the major axis of each of the oval shapes.

8. The semiconductor package of claim 6, wherein the maximum width of the top surface of each of the redistribution vias is smaller than a length of the major axis of each of the oval shapes.

9. The semiconductor package of claim 1, wherein:
the connection pads includes a first group of connection pads that are arranged linearly,
the plurality of connection wires includes a first group of connection wires connected to respective ones of the first group of connection pads,
at least some of the second portions of the first group of connection wires have oval shaped end surfaces of their corresponding second portions having major axes that extend in different alignment directions from one another.

10. The semiconductor package of claim 1, wherein:
in a plan view, the end surface of each of the second portions has an oval shape with a major axis and a minimum axis,
the plurality of semiconductor chips include a first semiconductor chip including first connection pads provided along a first edge of the first semiconductor chips,
the plurality of connection wires include first connection wires respectively connected to the first connection pads,
the first connection wires include a first group of connection wires and a second group of connection wires,
the major axis of each of the connection wires of the first group is aligned in a first horizontal direction,
the major axis of each of the connection wires of the second group is aligned in a second horizontal direction, and
the first horizontal direction intersects the second horizontal direction.

11. The semiconductor package of claim 1, wherein:
in a plan view, the end surface of each of the second portions has an oval shape with a major axis and a minimum axis,
the plurality of semiconductor chips include a first semiconductor chip including a first connection pad at a first edge of the first semiconductor chip, and a second semiconductor chip including a second connection pad at a second edge of the second semiconductor chip, the first edge of the first semiconductor chip being parallel to second edge of the second semiconductor chip,
the plurality of connection wires include a first connection wire connected to the first connection pad, and a second connection wire connected to the second connection pad,
the major axis of the first connection wires is aligned in a first horizontal direction,
the major axis of the second connection wires is aligned in a second horizontal direction, and
the first horizontal direction intersects the second horizontal direction.

12. A semiconductor package comprising:
a plurality of semiconductor chips respectively having a front surface on which connection pads are disposed and a rear surface opposite to the front surface, and stacked such that the front surface faces downwards;
a molded layer encapsulating the plurality of semiconductor chips;
a plurality of connection wires respectively extending from the connection pads of the plurality of semiconductor chips to a bottom surface of the molded layer; and
a package substrate disposed below the molded layer and including redistribution layers and redistribution vias electrically connecting the redistribution layers and the plurality of connection wires,
wherein:
each of the plurality of connection wires include a vertical portion extending from the connection pads in a direction toward the bottom surface of the molded layer, and a diagonal portion extending diagonally between the vertical portion and the redistribution vias, and the diagonal portion is exposed to the bottom surface of the molded layer and contacting the a corresponding one of redistribution vias, and
a maximum width of each of the diagonal portions exposed to the bottom surface of the molded layer is greater than a diameter of a corresponding one of the plurality of connection wires.

13. The semiconductor package of claim 12, wherein:
each of the diagonal portions includes a first sub-segment extending from the vertical portion and having a first inclination angle with respect to the bottom surface of the molded layer, and a second sub-segment extending from the first sub-segment and having a second inclination angle with respect to the bottom surface of the molded layer, and
the second inclination angle is different from the first inclination angle.

14. The semiconductor package of claim 12, wherein the plurality of connection wires include a first connection wire and a second connection wire spaced apart from each other,
the first connection wire includes a first diagonal portion having a first length in a first diagonal direction,
the second connection wire includes a second diagonal portion having a second length in the first diagonal direction or in a second diagonal direction, which is different from the first diagonal direction, and
the second length is different from the first length.

15. The semiconductor package of claim 12, wherein the plurality of connection wires include a first connection wire and a second connection wire spaced apart from each other,
the first connection wire includes a first diagonal portion having a first inclination angle with respect to the bottom surface of the molded layer,
the second connection wire includes a second diagonal portion having a second inclination angle with respect to the bottom surface of the molded layer, and
the second inclination angle is different from the first inclination angle.

16. The semiconductor package of claim 12, wherein the plurality of connection wires include a first connection wire and a second connection wire spaced apart from each other,
the first connection wire includes a first diagonal portion extending in a first diagonal direction,
the second connection wire includes a second diagonal portion extending in a second diagonal direction, and
the second diagonal direction is different from the first diagonal direction.

17. A semiconductor package comprising:
a plurality of semiconductor chips respectively having connection pads and stacked such that the connection pads face downwards;
a molded layer encapsulating the plurality of semiconductor chips;
a plurality of connection wires respectively extending from the connection pads of the plurality of semiconductor chips to a bottom surface of the molded layer; and
a package substrate disposed below the molded layer and including redistribution layers and redistribution vias electrically connecting the redistribution layers to the plurality of connection wires,
wherein:
each of the plurality of connection wires includes a vertical portion in contact with a corresponding one of the connection pads, and a diagonal portion extending diagonally between the vertical portion and a corresponding one of the redistribution vias, and the diagonal portion is exposed to the bottom surface of the molded layer and contacting the redistribution vias,
in a plan view, each of the diagonal portions have an end surface of oval shape exposed to the bottom surface of the molded layer,
the plurality of connection wires include a pair of connection wires that are adjacent to each other, and
the pair of connection wires have major axes of the oval shape respectively, and the major axes is different from each other.

18. The semiconductor package of claim 17, wherein each of the diagonal portions of the plurality of connection wires has an inclination angle with respect to the bottom surface of the molded layer, and the inclination angle is an angle within a range from 20° to 80°.

19. The semiconductor package of claim 17, wherein the molded layer includes:
a lower portion covering respective side surfaces of the plurality of semiconductor chips and a front surface of a lowermost semiconductor chip among the plurality of semiconductor chips, and
an upper portion covering a rear surface of an uppermost semiconductor chip among the plurality of semiconductor chips.

20. The semiconductor package of claim 19, wherein the lower portion and the upper portion include the same material.
